(19) United States
(12) Patent Application Publication
(10) Pub. No.: US 2021/0311843 A1
(43) Pub. Date: Oct. 7, 2021

(54) SYSTEM VERIFICATION PROGRAM GENERATION DEVICE, SYSTEM VERIFICATION PROGRAM GENERATION METHOD, AND RECORDING MEDIUM STORING SYSTEM VERIFICATION PROGRAM GENERATION PROGRAM

(71) Applicant: NEC Corporation, Tokyo (JP)

(72) Inventors: Kazuki TANABE, Tokyo (JP); Tatsuya FUKUDA, Tokyo (JP); Takayuki KURODA, Tokyo (JP)

(73) Assignee: NEC Corporation, Tokyo (JP)

(21) Appl. No.: 17/218,408

(22) Filed: Mar. 31, 2021

(30) Foreign Application Priority Data
Apr. 7, 2020 (JP) 2020-068942

(51) Int. Cl. G06F 11/22; G06F 11/263; G06F 11/30

(52) U.S. Cl. CPC G06F 11/2247; G06F 11/3051; G06F 11/263; G06F 11/2289

(57) ABSTRACT

The system verification program generation device 20 is equipped with a search unit 21 that searches a system design for execution entities and parameters of a verification program, which is a program that verifies whether the system design derived from system requirements satisfies one or more verification items extracted from the system requirements.

This application is based upon and claims the benefit of priority from Japanese patent application No. 2020-068942, filed on Apr. 7, 2020, the disclosure of which is incorporated here in its entirety by reference.

### BACKGROUND

### Technical Field

The present invention relates to a system verification program generation device, a system verification program generation method, and a recording medium storing a system verification program generation program. In particular, the present invention relates to a system verification program generation device, a system verification program generation method, and a recording medium storing a system verification program generation program capable of searching for program execution entities and parameters.

### Related Art

The process of constructing an ICT (Information Communication Technology) system, which consists of servers and network equipment, etc., can be generally classified into one of the following five processes: requirements definition process, basic design process, detailed design process, deployment process, and verification process, mainly.

In the construction work of ICT systems, engineers often perform the above five processes manually. However, each process (especially the basic design process, the detailed design process, and the deployment process) is also often automated by the use of specialized tools.

Takayuki Kuroda, Takuya Kuwahara, Takashi Maruyama, “Intent-based IT Service Configuration Designing and Application of Machine Learning,” 2019 IEICE Society Conference, BI-6-4, September 2019. and T. Kuroda, T. Kuwahara, T. Maruyama, K. Satoda, H. Shimonishi, T. Osaki, and K. Matsuda, “Weaver: A Novel Configuration Designer for IT/NW Services in Heterogeneous Environments,” in Proceedings of IEEE GLOBECOM 2019, pp. 1-6, December, 2019. describe a technique for automatically generating system designs on the basis of system requirements, with the aim of automating the basic design process and the detailed design process.

The techniques described in Takayuki Kuroda, Takuya Kuwahara, Takashi Maruyama, “Intent-based IT Service Configuration Designing and Application of Machine Learning,” 2019 IEICE Society Conference, BI-6-4, September 2019. and T. Kuroda, T. Kuwahara, T. Maruyama, K. Satoda, H. Shimonishi, T. Osaki, and K. Matsuda, “Weaver: A Novel Configuration Designer for IT/NW Services in Heterogeneous Environments,” in Proceedings of IEEE GLOBECOM 2019, pp. 1-6, December, 2019. take system requirements as input, generate a system design that satisfies the input system requirements, and output the generated system design.

The above input system requirements are described, for example, by a combination of multiple underlying requirements. The output system design above is generated, for example, by performing a computation that aims to satisfy all the underlying requirements.

In addition, “Red Hat Ansible”, [online], Red Hat (registered trademark), [retrieved Mar. 16, 2020]. and “Chef”, [online], Chef (registered trademark), [retrieved Mar. 16, 2020]. describe configuration management tools that aim to automate the deployment of ICT systems.

The configuration management tools described in “Red Hat Ansible”, [online], Red Hat (registered trademark), [retrieved Mar. 16, 2020]. and “Chef”, [online], Chef (registered trademark), [retrieved Mar. 16, 2020]. describe the user's desired ICT system configuration according to a predetermined specification and in accordance with the notation of the program. In other words, users of the configuration management tools described in “Red Hat Ansible”, [online], Red Hat (registered trademark), [retrieved Mar. 16, 2020]. and “Chef”, [online], Chef (registered trademark), [retrieved Mar. 16, 2020]. can automatically generate the works required to change the configuration of the ICT system from the current state to the described state, without considering the dependencies between the work steps.

In the verification process where it is verified whether the deployed system satisfies the given system requirements, for example, single or multiple verification items are generated to check whether the system requirements are satisfied. For each generated verification item, for example, a system verification program (hereinafter referred to as also a verification program) is generated, respectively.

In generating the verification program, it is required to refer to the system configuration (design) and modify the verification program according to the referenced system configuration. For example, it is required to modify the commands that compose the program according to the OS (Operating System) that executes the program.

In addition, in the generation of the verification program, the IP (Internet Protocol) address and MAC (Media Access Control) address, which are the destination of the communication specified in the verification program, and the URL (Uniform Resource Locator) and other information are also required to set as arguments (parameters).

After the verification program is generated, the generated verification program is executed in the deployed system. Then, based on the execution results of the verification program, it is determined whether each verification item is satisfied. The verification process, which includes from the generation of the verification program to the judgment of each verification item, is often performed manually.

Also, “Cypher Query Language”, [online], Neo4j (registered trademark), [retrieved Mar. 16, 2020]. describes a declarative graph query language developed for data processing of graph structures.

### SUMMARY

The problem with the manual verification process is that it places a heavy burden on the engineers because they have to manually generate different verification programs for each system design that is automatically generated from several different system requirements.

The reason for the above is that the content of the verification program, such as the program execution entity and parameters, changes according to the specific system configuration (design) of the verification target, and thus the verification program description is required to be modified for each system design. Takayuki Kuroda, Takuya Kuwahara, Takashi Maruyama, “Intent-based IT Service Configuration Designing and Application of Machine Learning,” 2019 IEICE Society Conference, BI-6-4, September 2019., T. Kuroda, T. Kuwahara, T. Maruyama, K. Satoda, H. Shimonishi, T. Osaki, and K. Matsuda, “Weaver: A Novel Configuration Designer for IT/NW Services in Heterogeneous Environments,” in Proceedings of IEEE GLOBECOM 2019, pp. 1-6, December, 2019., “Red Hat Ansible”, [online], Red Hat (registered trademark), [retrieved Mar. 16, 2020]., “Chef”, [online], Chef (registered trademark), [retrieved Mar. 16, 2020]., and “Cypher Query Language”, [online], Neo4j (registered trademark), [retrieved Mar. 16, 2020]. do not describe the technology to automatically generate verification programs according to the system configuration.

Therefore, one of the purposes of the present invention is to provide a system verification program generation device, a system verification program generation method, and a recording medium storing a system verification program generation program that can reduce the burden on engineers in generating system verification programs.

In an exemplary embodiment of the present invention, a system verification program generation device is configured to search a system design for execution entities and parameters of a verification program, which is a program that verifies whether the system design derived from system requirements satisfies one or more verification items extracted from the system requirements.

In an exemplary embodiment of the present invention, the system verification program generation method searches a system design for execution entities and parameters of a verification program, which is a program that verifies whether the system design derived from system requirements satisfies one or more verification items extracted from the system requirements.

In an exemplary embodiment of the present invention, a non-transitory computer readable recording medium storing a system verification program generation program causes a computer to: search a system design for execution entities and parameters of a verification program, which is a program that verifies whether the system design derived from system requirements satisfies one or more verification items extracted from the system requirements.

This invention can reduce the burden on engineers to generate system verification programs.

### BRIEF DESCRIPTION OF DRAWINGS

FIG. 1 is a block diagram showing an example of the configuration of a system verification program generation device of an exemplary embodiment of the invention;

FIG. 2 is an explanatory diagram showing an example of a system requirement;

FIG. 3 is a block diagram showing an example of the system requirement;

FIG. 4 is an explanatory diagram showing a correspondence between system requirements, verification items, and a group of verification items;

FIG. 5 is an explanatory diagram showing an example of a data structure (data set) that forms a verification template;

FIG. 6 is an explanatory diagram showing an example of a method of describing a search procedure;

FIG. 7 is an explanatory diagram showing an example of the search process when the search procedure is applied to a system design;

FIG. 8 is an explanatory diagram showing an example of a system design;

FIG. 9 is a block diagram showing an example of a system design;

FIG. 10 is an explanatory diagram showing an example of a data structure (data set) that forms a command template;

FIG. 11 is an explanatory diagram showing an example of a group of verification programs;

FIG. 12 is a flowchart showing the operation in system verification program generation processing performed by the system verification program generation device 100 of present exemplary embodiment;

FIG. 13 is a block diagram showing a modification example of a system verification program generation device;

FIG. 14 is an explanatory diagram showing an example of verification results;

FIG. 15 is an explanatory diagram showing another example of the verification results;

FIG. 16 is a flowchart showing the other operation in system verification program generation processing performed by the system verification program generation device 100 of present exemplary embodiment;

FIG. 17 is a schematic block diagram showing an example of the configuration of a computer in which the system verification program generation device 100 of present exemplary embodiment is implemented; and

FIG. 18 is a block diagram showing an outline of the system verification program generation device according to the present invention.

### DETAILED DESCRIPTION

[Description of Configuration]

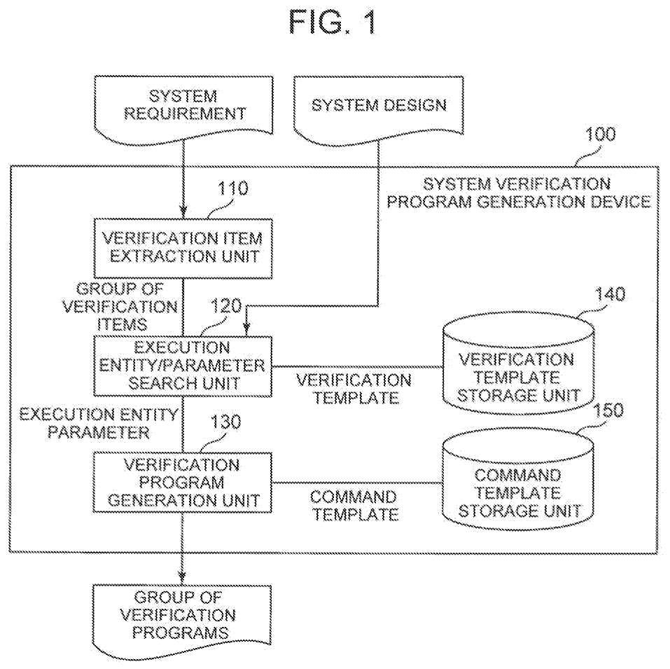

An exemplary embodiment of the present invention will be described below with reference to the drawings. FIG. 1 is a block diagram showing an example of the configuration of a system verification program generation device of an exemplary embodiment of the invention.

For a single system requirement and a single system design, the system verification program generation device of this exemplary embodiment generates a system verification program that verifies whether the system design satisfies the system requirement, without manual intervention. In other words, the system verification program generation device of this exemplary embodiment can reduce the burden on engineers for generating system verification programs.

As shown in FIG. 1, the system verification program generation device 100 of this exemplary embodiment includes a verification item extraction unit 110, an execution entity/parameter search unit 120, a verification program generation unit 130, a verification template storage unit 140, and a command template storage unit 150.

As shown in FIG. 1, the system verification program generation device 100 takes the system requirements and system design as input, and a group of verification programs as output.

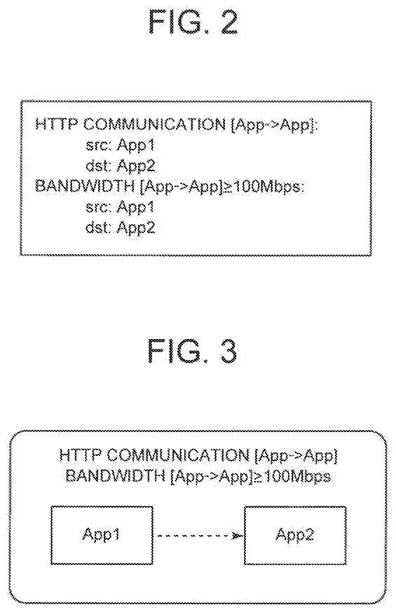

The system requirements in this exemplary embodiment describes the conditions of the functions that the system is required to achieve in an abstract form. FIG. 2 is an explanatory diagram showing an example of a system requirement.

As shown in FIG. 2, system requirements are defined using, for example, components, which are the elements that make up the system, and the connection relationships between the components. The components shown in FIG. 2 are “App1” and “App2”. The connection relationships between the components shown in FIG. 2 are “HTTP (Hyper Text Transfer Protocol) communication [App->App]” and “Bandwidth [App->App]≥100 Mbps”.

FIG. 3 is a block diagram showing an example of the system requirement. The system requirements shown in FIG. 3 are the system requirements shown in FIG. 2, represented in a graph structure.

In the notation in FIG. 3, the components of the system, such as applications and operating systems, are represented as nodes (vertices). For example, as shown in FIG. 3, the components “App1” and “App2” are represented as nodes, respectively.

In addition, in the notation in FIG. 3, the connection relationship between each component is expressed as an edge (branch). For example, as shown in FIG. 3, the connection relationship “HTTP communication [App->App]” is expressed as a dashed edge extending from “App1” to “App2”. For the sake of simplicity, the same notation will be used in other drawings.

FIG. 3 shows two requirements: HTTP communication must be possible between Application App1 and Application App2, and the communication bandwidth between the two applications must be at least 100 Mbps.

FIG. 2 also shows the same system requirements as shown in FIG. 3. The specific content and format of the system requirements are not limited to the examples shown in FIGS. 2 to 3.

The verification item extraction unit 110 has the function of extracting a group of verification items consisting of single or multiple verification items from the input system requirements.

The verification items in this exemplary embodiment are the conditions of the functions that are required to be achieved, which are described in the system requirements, and which are divided into units where the verification method using the program are predefined.

The group of verification items consists of single or multiple verification items. When all the verification items in a group of verification items are satisfied, the system design is determined to satisfy the system requirements.

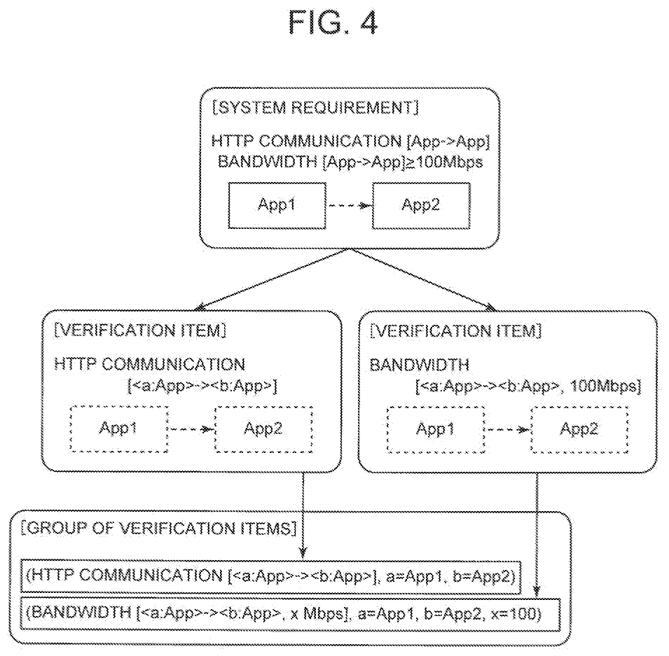

FIG. 4 is an explanatory diagram showing a correspondence between system requirements, verification items, and a group of verification items. The system requirements shown in FIG. 4 are the system requirements shown in FIG. 3.

The verification items shown in FIG. 4 are “HTTP communication [<a:App>-><b:App>]” and “bandwidth [<a:App>-><b:App>, 100 Mbps],” which are the conditions for the functions described in the system requirements. Note that <a:App> and <b:App> refer to App1 and App2, respectively. The group of verification items shown in FIG. 4 consists of the two verification items shown in FIG. 4.

For the input system requirements, the verification item extraction unit 110 determines, for example, whether the connection relationships match the verification items specified in the verification template stored in the verification template storage unit 140, for all the connection relationships included in the system requirements.

If the connection relation matches the verification item specified in the verification template, the verification item extraction unit 110 extracts the matching verification item and the set of the start point and the end point of the connection relation that is the verification item. Next, the verification item extraction unit 110 adds the extracted verification items and the sets of the start and end points to the group of verification items.

If there are multiple different verification items (connection relations) between the same start and end points, the verification item extraction unit 110 adds them to the group of verification items as independent verification items.

Verification items can also be items related to functions other than connection relationships. For example, the verification items can be items related to checking the operation of individual system components.

The execution entity/parameter search unit 120 obtains the verification template corresponding to the extracted verification item from the verification template storage unit 140. Next, the execution entity/parameter search unit 120 obtains the search procedure for the execution entity of the command and the search procedure for the parameter described in the obtained verification template, respectively.

The verification template in this exemplary embodiment is a template whose main item is the verification item. The verification template specifies the type of command that constitutes the verification program corresponding to the verification item, the execution entity of the command (Agent), and the search procedure for the parameter. The verification template is stored in the verification template storage unit 140.

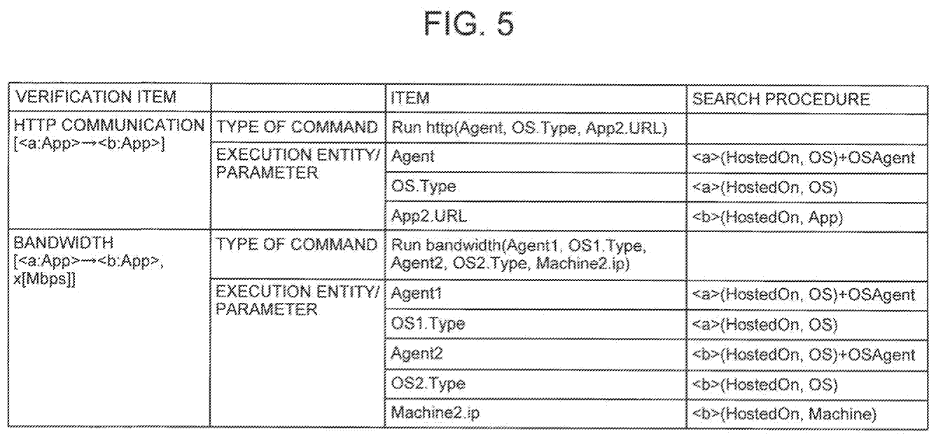

FIG. 5 is an explanatory diagram showing an example of a data structure (data set) that forms a verification template. As shown in FIG. 5, the verification template specifies, for example, the type of command required to verify each verification item, the execution entity and parameters required to execute the command, and the search procedure for the execution entity and parameters, respectively.

For example, in the case of the verification item “HTTP communication [<a:App>-><b:App>]”, “Run http(Agent, OS.Type, App2.URL)” is specified as the type of command. In addition, “Agent” is specified as the execution entity. In addition, “OS.Type” and “App2.URL” are specified as parameters, respectively.

As a search procedure, for example, “<a>(HostedOn, OS)+OSAgent” is specified for the executing entity “Agent”. Note that <a> and <b> shown in FIG. 5 mean App1 and App2, respectively.

The search procedure shown in FIG. 5 defines how to trace components in the system design and the connection relationships among the components in order to reach the execution entity or parameter of the command from the start point in the system design given as an argument.

For example, the search procedure can be described using an abstract representation of the graph structure, as described in “Cypher Query Language”, [online], Neo4j (registered trademark), [retrieved Mar. 16, 2020]. As a simpler method, it is also possible to describe the search procedure using regular expressions used for string search. In the following, we show an example of using regular expressions in this exemplary embodiment.

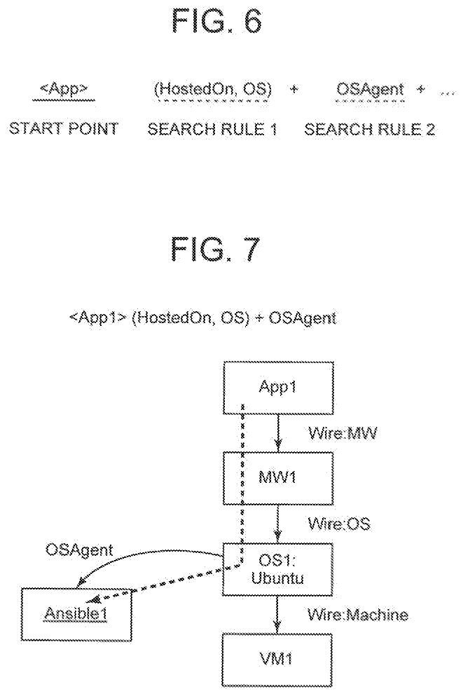

FIG. 6 is an explanatory diagram showing an example of a method of describing a search procedure. As shown in FIG. 6, for example, the search procedure consists of the start point of the search, which is described in the symbol “< >”, and the search rules 1, 2, . . . , and n, which are separated by the symbol “+”.

Each search rule is executed in the order of search rule 1, search rule 2, . . . , and search rule n. The search procedure shown in FIG. 6, “<App> (HostedOn, OS)+OSAgent,” means that the component App is the start point of the search, the connection relation HostedOn is repeatedly traced one or more times, and the first OS-type component reached is the search result. The search procedure shown in FIG. 5 is described using the notation shown in FIG. 6.

FIG. 7 is an explanatory diagram showing an example of the search process when the search procedure is applied to a system design. The following is an example of the search process when the search procedure “<App1>(HostedOn, OS)+OSAgent” shown in FIG. 7 is applied to the system design shown in FIG. 7.

The search rule “(HostedOn, OS)” means that the connection relation HostedOn is repeatedly traced one or more times, and the first OS-type component reached is the search result. Note that the connection relation HostedOn represents a relationship in which one component is hosted by another component.

An inheritance relationship is included the component types and the connection relationship types of the system in this exemplary embodiment. Specifically, it is defined in the execution entity/parameter search unit 120 that “Wire:OS,” “Wire:Machine,” “Wire:NIC,” and “Wire:Router” are each a connection relationship inherited from the connection relationship HostedOn. In other words, in the system design shown in FIG. 7, “Wire:OS”, “Wire:Machine”, “Wire:NIC”, and “Wire:Router” all correspond to the connection relationship HostedOn.

The search rule “OSAgent” means that the search results will be the components connected by the connection relation OSAgent.

The execution entity/parameter search unit 120, which follows the search procedure shown in FIG. 7, starts the search process with the start point at the component App1. The execution entity/parameter search unit 120 first follows the search rule 1 “(HostedOn, OS)” and moves to the component MW1 by following the connection relation Wire:MW belonging to the connection relation HostedOn.

Since the component MW1 is an MW type, the execution entity/parameter search unit 120 further follows the connection relation Wire:OS belonging to the connection relation HostedOn and moves to the component OS1:Ubuntu. Since the component OS1:Ubuntu is an OS type, the execution entity/parameter search unit 120 completes the process according to the search rule 1.

Next, the execution entity/parameter search unit 120 moves from the component OS1:Ubuntu to the component Ansible1 connected by the connection relation OSAgent according to the search rule 2 “OSAgent”. The execution entity/parameter search unit 120 returns the component Ansible1 as the search result, and ends the process according to the search rule 2 and the search process.

As shown in FIG. 7, the execution entity/parameter search unit 120 searches for the execution entity and parameters of commands for each verification item by applying the obtained search procedure to the input system design.

As described above, the verification template storage unit 140 stores verification templates, which are templates that specify verification items, search procedures corresponding to execution entities, and search procedures corresponding to parameters, respectively, associated with them.

In addition, the execution entity/parameter search unit 120 extracts the search procedure corresponding to the execution entity and the search procedure corresponding to the parameter from the verification template that contains the verification items to be verified, respectively. Then, the execution entity/parameter search unit 120 searches for the execution entity and parameters of the verification program using the extracted search procedures, respectively.

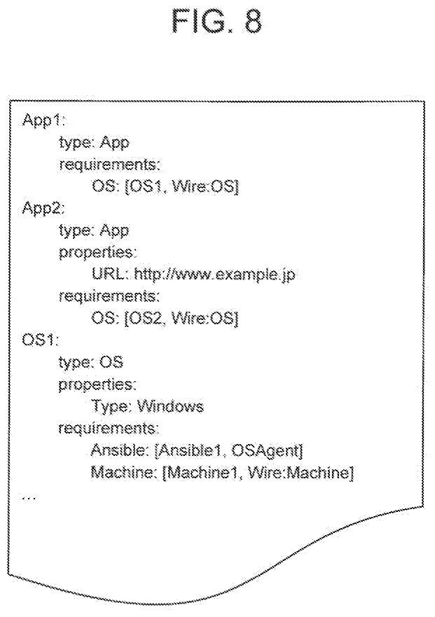

In the system design of this exemplary embodiment, the components of the system and the relationship between each component are defined to the extent that they can be deployed. FIG. 8 is an explanatory diagram showing an example of a system design.

As shown in FIG. 8, for example, each component of the system is described as a main item in the system design. For example, in FIG. 8, “App1”, “App2”, and “OS1” are described as the main items, respectively.

In addition, as shown in FIG. 8, the system design describes, for example, the component type (type), attribute values (properties), and connection relationships (requirements), equivalent to the main items, respectively.

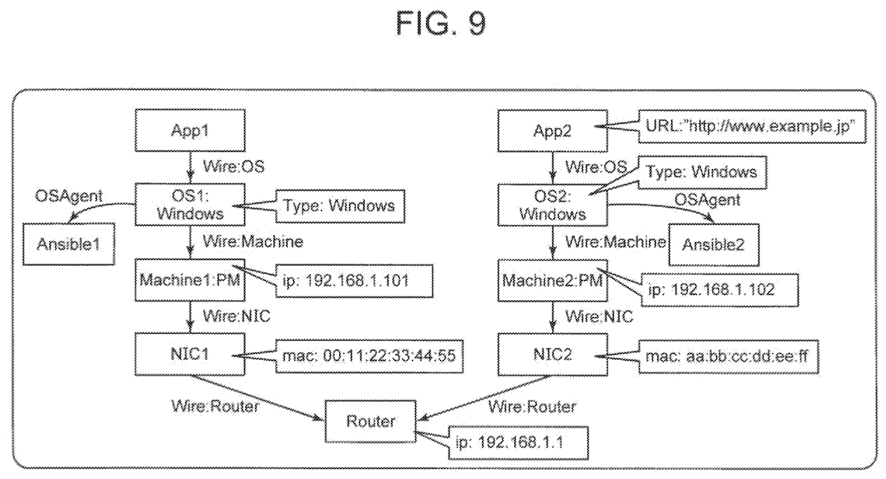

FIG. 9 is a block diagram showing an example of a system design. The system design shown in FIG. 9 is the system design shown in FIG. 8, represented by a graph structure. First, we will explain the example shown in the right side of FIG. 9. In the example shown in the right side of FIG. 9, the application App2 holds the URL (“http://www.example.jp”) required to access itself as a parameter. In addition, OS2, which hosts the application App2, holds a Type value (“Windows”), which indicates the OS type, as a parameter.

OS2 is also connected to Ansible2, which is an Agent that is the execution entity of the program. In addition, Machine2, which is the physical machine on which OS2 is installed, holds the IP address value (“192.168.1.102”) as a parameter.

NIC (Network Interface Card) 2 to which Machine2 connects holds the MAC address value (“aa:bb:cc:dd:ee:ff”) as a parameter. The router (Router) to which NIC2 connects holds the IP address value (“192.168.1.1”) as a parameter.

Next, we will explain the example shown in the left side of FIG. 9. In the example shown in the left side of FIG. 9, OS1, which hosts the application App1, holds the Type value (“Windows”), which indicates the OS type, as a parameter.

OS1 is also connected to Ansible1, which is an Agent that is the execution entity of the program. In addition, Machine1, which is the physical machine on which OS1 is installed, holds the IP address value (“192.168.1.101”) as a parameter.

NIC1, to which Machine1 connects, also holds the MAC address value (“00:11:22:33:44:55”) as a parameter.

FIG. 8 also shows the same system design as shown in FIG. 9. The specifics and format of the system design are not limited to the examples shown in FIGS. 8 to 9.

In the case of the example shown in FIG. 9, the execution entity/parameter search unit 120 searches for the execution entity and parameter corresponding to the verification item “HTTP communication [<a:App>-><b:App>]” as “Agent=Ansible1, OS.Type=Windows, App2.URL=http://www.example.jp”.

In addition, the execution entity/parameter search unit 120 searches for the execution entity and parameter corresponding to the verification item “Bandwidth[<a:App>→<b:App>, x[Mbps]” as “Agent1=Ansible1, OS1.Type=Windows, Agent2=Ansible2, OS2.Type=Windows, Machine2.ip=192.168.1.102”. The execution entity/parameter search unit 120 inputs the searched execution entity and parameters to the verification program generation unit 130.

The verification program generation unit 130 refers to the command templates stored in the command template storage unit 150 using the execution entities and parameters of the commands searched for each verification item.

Next, the verification program generation unit 130 generates the verification program by assigning parameters to the corresponding command obtained from the referenced command template. Note, in this exemplary embodiment, the script corresponds to the command.

The command template of this exemplary embodiment specifies the correspondence between the types of commands and scripts for converting the types of commands that constitute the verification program into concrete scripts, and the method of assigning arguments to the scripts, respectively.

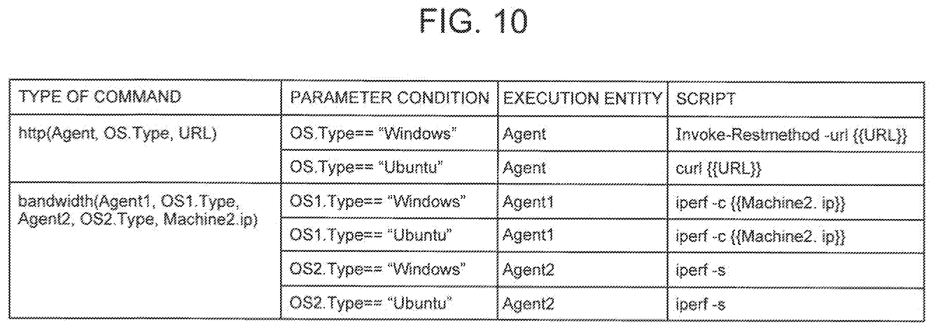

FIG. 10 is an explanatory diagram showing an example of a data structure (data set) that forms a command template. As shown in FIG. 10, a command template is a template whose main item is the type of command obtained from a verification template, for example. In addition, a single command template specifies a pair consisting of, for example, the parameter conditions of the command, the execution entity of the command, and the script corresponding to the command, respectively.

For example, as shown in FIG. 10, a command template whose the type of command is “http(Agent, OS.Type, URL)” specifies a pair of the “OS.Type==“Windows”” as the parameter condition, “Agent” as the executing entity, and “Invoke-Restmethod -url {{URL}}” as the script.

Each script shown in FIG. 10 consists of a single or multiple instruction sentences. When a parameter variable is included in an instruction statement, the verification program generation unit 130 returns the reference result when the corresponding parameter that was searched for is assigned.

For example, we consider the case where the verification program generation unit 130 refers to a command template whose the type of command is “http(Agent, OS.Type, URL)”. When “OS.Type=Windows, App2.URL=http://www.example.jp” is input as a parameter, the parameter satisfies the parameter condition “OS.Type==“Windows””.

Therefore, the verification program generation unit 130 returns a set of “Execution entity: Ansible1, Script: Invoke-Restmethod -url http://www.example.jp” as a reference result, which is the set of the input execution entity and scripts to which parameters are assigned.

If the input parameter satisfies multiple parameter conditions, the verification program generation unit 130 obtains all the sets of the corresponding execution entities and scripts, and returns them as reference results.

For example, we consider the case where the verification program generation unit 130 refers to a command template whose the type of command is “bandwidth(Agent1, OS1.Type, Agent2, OS2.Type, Machine2.ip)”. If “OS1.Type=Windows, OS2.Type=Windows, Machine2.ip=192.168.1.102” is input as a parameter, the parameter satisfies two parameter conditions “OS1.Type==“Windows”” and “OS2.Type==“Windows””.

Therefore, the verification program generation unit 130 returns two sets of “Execution entity: Ansible1, Script: iperf -c 192.168.1.102” and “Execution entity: Ansible2, Script: iperf -s” as the reference results which are the sets of the input execution entity and scripts to which parameters are assigned.

The command template is not limited to the example shown in FIG. 10. Commands may also be expressed in a format other than script.

A verification program in this exemplary embodiment is a program that is executed to verify a single verification item. In addition, a group of verification programs is a set of verification programs that are executed to confirm that the system design satisfies the system requirements. In other words, a group of verification programs consists of a single or multiple verification programs.

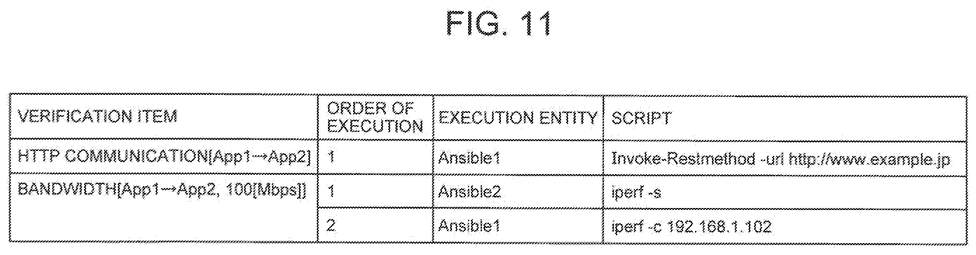

FIG. 11 is an explanatory diagram showing an example of a group of verification programs. The group of verification programs shown in FIG. 11 is an example of a group of verification programs obtained by inputting the system requirements shown in FIG. 3 and the system design shown in FIG. 9 into the system verification program generation device 100, respectively.

As shown in FIG. 11, a verification program consists of, for example, the order of script execution, the execution entity of script, and the script body. The content of each verification program shown in FIG. 11 corresponds to each reference result returned by the verification program generation unit 130 described above, respectively.

In other words, the group of verification programs shown in FIG. 11 includes verification programs for the verification item “HTTP communication [App1→App2]” and the verification item “Bandwidth [App1→App2, 100[Mbps]]” respectively. The verification program generation unit 130 generates a group of verification programs on the basis of each reference result, and outputs the generated group of verification programs.

As described above, the command template storage unit 150 stores command templates, which are templates in which the executing entity, parameters, and commands (scripts in this example) that constitute the verification program are associated and specified, respectively.

The verification program generation unit 130 extracts a command from the command template that contains the searched execution entity and parameters, and assigns the searched parameters to the arguments of the extracted command.

The system verification program generation device 100 of this exemplary embodiment includes a verification item extraction unit 110 that extracts a group of verification items consisting of single or multiple verification items from the input system requirements (i.e., extracts one or more verification items from the system requirements).

The system verification program generation device 100 also includes an execution entity/parameter search unit 120 that searches for the execution entity and parameters of the verification program from the system design derived from the system requirements for each verification item included in the group of verification items.

As described above, the verification program of this exemplary embodiment is a program that verifies whether the system design derived from the system requirements satisfies one or more verification items extracted from the system requirements.

In addition, the execution entity/parameter search unit 120 searches for execution entities and parameters using a search procedure, which is a procedure for searching execution entities and parameters of a verification program from the system design.

The system verification program generation device 100 also includes a verification program generation unit 130 that generates verification programs by assigning the searched parameters to the arguments of the commands that constitute the verification program.

The system verification program generation device 100 of this exemplary embodiment can generate multiple verification programs for multiple system designs derived from the system requirements, each without manual modification. The reason is that the execution entity/parameter search unit 120 extracts the execution entity and parameters of the verification program corresponding to each of the multiple different system designs, and the verification program generation unit 130 assigns the extracted parameters to the commands that constitute the verification program.

[Description of Operation]

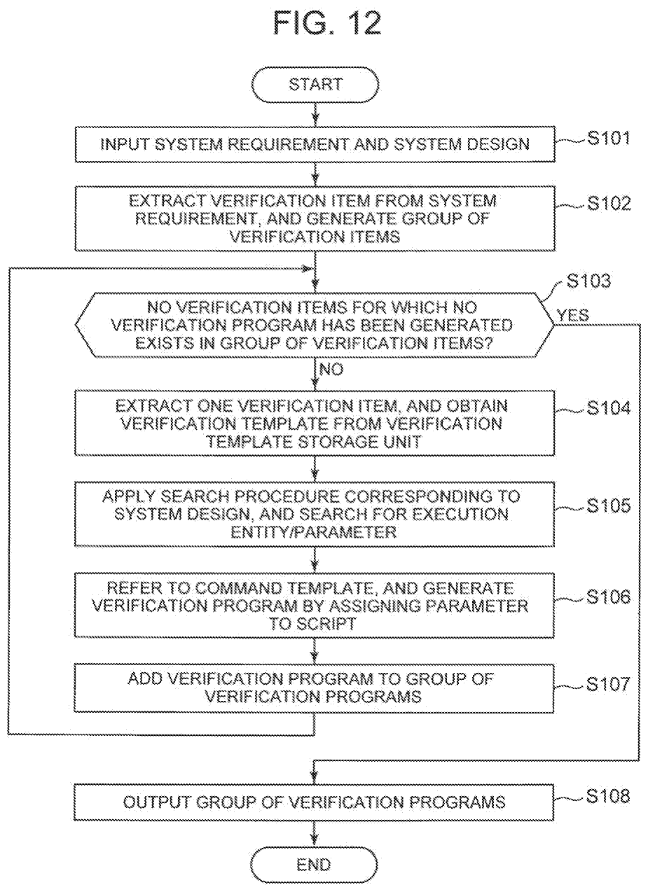

The operation of the system verification program generation device 100 of this exemplary embodiment will be described below with reference to FIG. 12. FIG. 12 is a flowchart showing the operation in system verification program generation processing performed by the system verification program generation device 100 of this exemplary embodiment.

First, the system requirements and the system design derived from the system requirements are input to the system verification program generation device 100, respectively (Step S101).

Next, the verification item extraction unit 110 of the system verification program generation device 100 extracts one or more verification items from the system requirements. Next, the verification item extraction unit 110 generates a group of verification items consisting of the extracted verification items (Step S102). Next, the verification item extraction unit 110 inputs the generated group of verification items to the execution entity/parameter search unit 120.

Next, the execution entity/parameter search unit 120 determines whether there are any verification items for which no verification program has been generated in the input group of verification items (Step S103).

If there is a verification item for which no verification program has been generated in the group of verification items (No in step S103), the execution entity/parameter search unit 120 extracts one verification item for which no verification program has been generated from the input group of verification items.

Next, the execution entity/parameter search unit 120 refers to the verification template storage unit 140 to obtain a verification template containing verification items that match the extracted verification items (Step S104).

Next, the execution entity/parameter search unit 120 applies the search procedure for the execution entity of commands and the search procedure for parameters described in the verification template obtained in step S104 to the input system design. By applying the search procedure to the system design, the execution entity/parameter search unit 120 searches for the execution entity and parameters corresponding to the extracted verification items (Step S105).

Next, the execution entity/parameter search unit 120 inputs the type of command described in the verification template obtained in step S104 and the searched execution entity and parameters to the verification program generation unit 130.

Next, the verification program generation unit 130 refers to the command template stored in the command template storage unit 150.

Specifically, the verification program generation unit 130 refers to the command template whose parameter conditions and execution entity match the inputted parameters and execution entity among the command templates corresponding to the inputted the type of commands. Next, the verification program generation unit 130 obtains the script of the referenced command template.

Next, the verification program generation unit 130 generates the verification program by assigning the corresponding inputted parameters to the obtained script (Step S106).

Next, the verification program generation unit 130 adds the generated verification program to the group of verification programs (step S107). After the verification program is added, the system verification program generation device 100 performs the process of step S103 again.

If there is no verification item for which a verification program has not been generated in the group of verification items (Yes in step S103), the verification program generation unit 130 outputs the group of verification programs (step S108). After outputting the group of verification programs, the system verification program generation device 100 ends the system verification program generation process.

[Description of Effects]

In the system verification program generation device 100 of this exemplary embodiment, for each of one or more verification items extracted from the system requirements by the verification item extraction unit 110, the execution entity/parameter search unit 120 applies the search procedure specified in the verification template to the system design. By applying the search procedure to the system design, the execution entity/parameter search unit 120 searches for the execution entity and parameters of the verification program. Next, the verification program generation unit 130 generates the verification program by assigning the parameters to the script specified in the command template.

Therefore, the system verification program generation device 100 of this exemplary embodiment searches for the execution entity and parameters of the verification program for each of the multiple system designs derived from the system requirements, so that an appropriate group of verification programs for each system design can be generated without manual modification.

When the system verification program generation device 100 of this exemplary embodiment is used, the verification process of ICT systems can be made faster and more labor-saving. Since the system verification program generation device 100 uses the search procedure specified in the verification template, for example, it can generate multiple different verification programs for multiple different system designs derived from the same system requirements, respectively.

The system verification program generation device 100 of this exemplary embodiment is used, for example, to verify whether a network system constructed according to the system design operates as per the system requirements.

### Modification Example

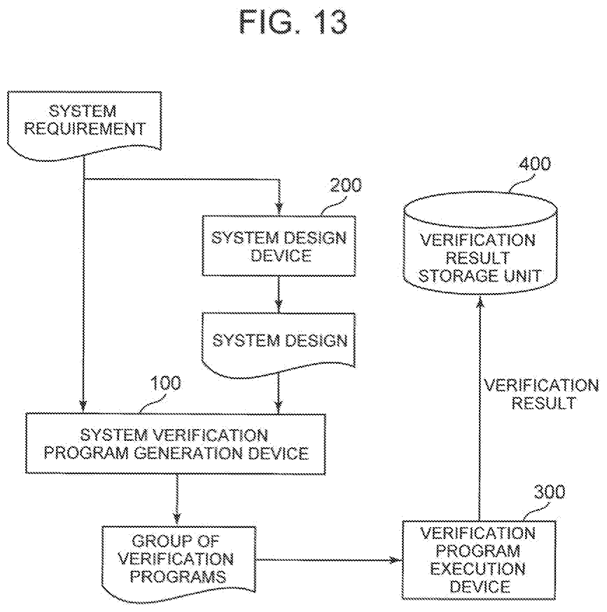

Next, we will explain a modification example of this exemplary embodiment. FIG. 13 is a block diagram showing a modification example of a system verification program generation device.

As shown in FIG. 13, the system verification program generation device 100 is communicatively connected to the system design device 200 and the verification program execution device 300. The verification program execution device 300 is also communicatively connected to the verification result storage unit 400.

The system design device 200 is a device that takes system requirements as input and outputs a system design corresponding to the input system requirements.

The verification program execution device 300 is a device that takes the group of verification programs as input and executes the script described in the verification program for each verification program included in the group of verification programs according to the execution order and execution entity described in the verification program.

Specifically, the verification program execution device 300 causes the execution entity described in the verification program to execute the script in the execution order described in the verification program. After executing the script, the verification program execution device 300 outputs the verification results.

The verification result storage unit 400 has the function of storing the verification results output from the verification program execution device 300.

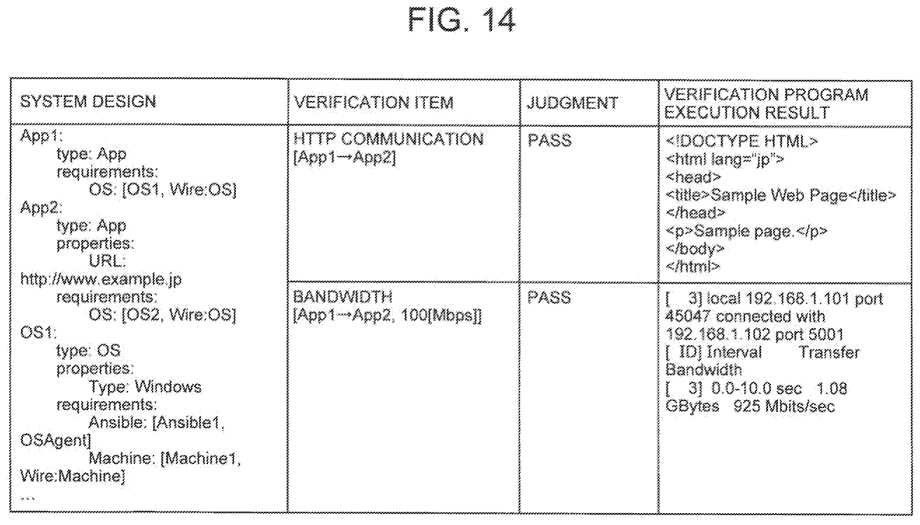

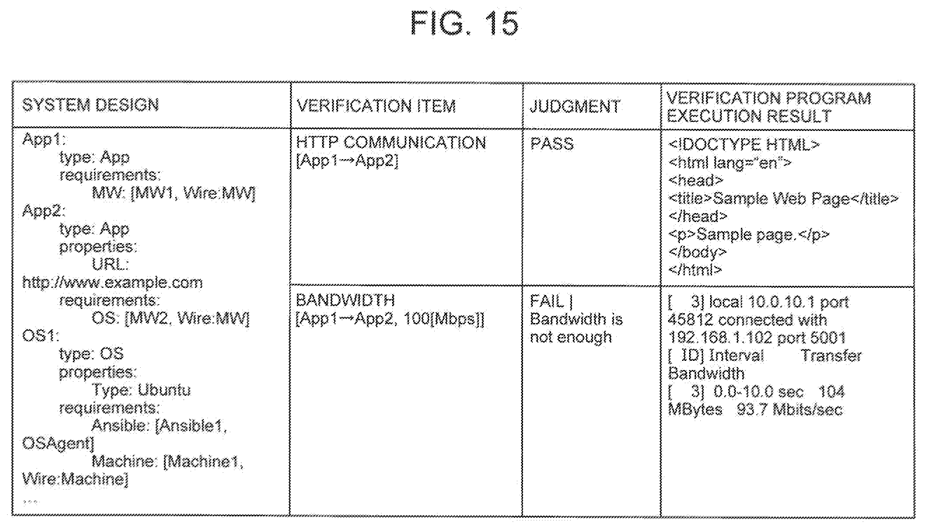

FIGS. 14 to 15 show an example of verification results. The verification results shown in FIGS. 14 to 15 consist of the system design that has been verified, the verification items, the judgment that indicates whether the verification items are satisfied, and the verification program execution results.

In this modification example, the verification program execution device 300 can perform verification on a large number of system designs derived by the system design device 200 from various system requirements. As the verification program execution device 300, a device that executes verification programs for the purpose of, for example, verifying the operation of a new product in various settings and environments, or generating a large amount of training data required for executing machine learning, can be used.

[Description of Operation]

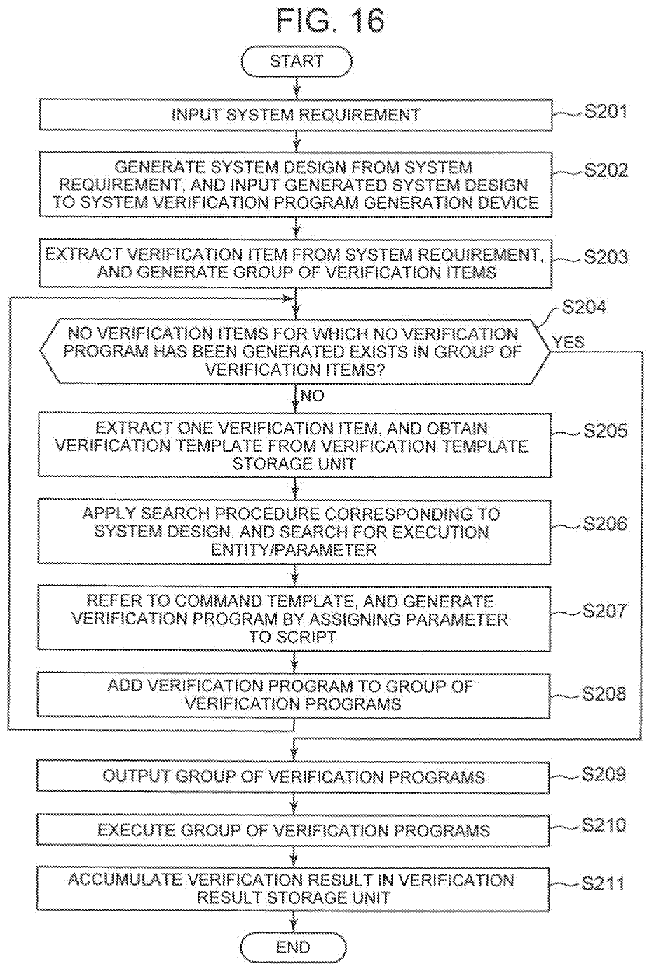

The operation of the system verification program generation device 100 of this modification example will be described below with reference to FIG. 16. FIG. 16 is a flowchart showing the other operation in system verification program generation processing performed by the system verification program generation device 100 of this exemplary embodiment.

First, the system requirements are input to the system design device 200 and the system verification program generation device 100, respectively (Step S201).

Next, the system design device 200 generates a system design on the basis of the input system requirements. Next, the system design device 200 inputs the generated system design to the system verification program generation device 100 (Step S202).

Each process of step S203 to step S209 is the same as each process of step S102 to step S108 shown in FIG. 12. In step S209, the group of verification programs output from the verification program generation unit 130 is input to the verification program execution device 300.

Next, the verification program execution device 300 executes the input group of verification programs and outputs the verification results (Step S210). Next, the verification program execution device 300 accumulates the output verification results in the verification result storage unit 400 (Step S211). After the verification results have been accumulated, the system verification program generation device 100 ends the system verification program generation process.

[Description of Effects]

In this modification example, the system verification program generation device 100, in which the system requirements and the system design generated by the system design device 200 from the system requirements are input, generates a group of verification programs. Next, the verification program execution device 300 executes the group of verification programs and stores the verification results output by executing the group of verification programs in the verification result storage unit 400.

Therefore, in this modification example, since the verification results output at the time of execution of a group of verification programs are stored in the verification result storage unit 400, it is possible to accumulate a vast amount of verification results for a large number of system requirements and system designs.

In addition, in this modification example, since the system design device 200 generates the system design from the system requirements, automation of the basic and detailed design process to the verification process in the process of ICT system construction work is realized.

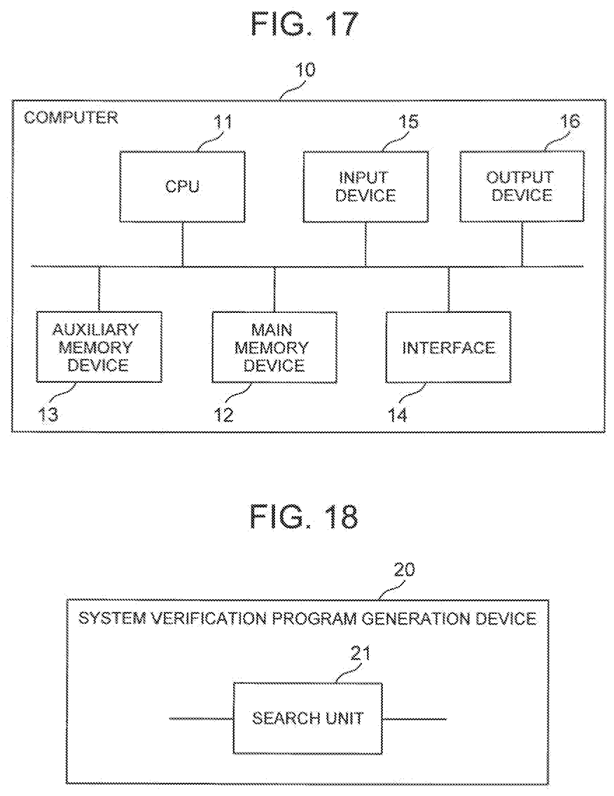

FIG. 17 is a schematic block diagram showing an example of the configuration of a computer in which the system verification program generation device 100 of this exemplary embodiment is implemented. The computer 10 shown in FIG. 17 is equipped with a Central Processing Unit (CPU) 11, a main memory device 12, an auxiliary memory device 13, an interface 14, an input device 15, and an output device 16.

The system verification program generation device 100 of this exemplary embodiment is implemented in a computer 10. A system verification program generation program that realizes the operation of the system verification program generation device 100 is stored in the auxiliary memory device 13.

The CPU 11 reads the system verification program generation program from the auxiliary memory device 13, expands it to the main memory device 12, and executes the processes described in the above exemplary embodiment according to the expanded system verification program generation program. The main memory device 12 is, for example, RAM (Random Access Memory).

The auxiliary memory device 13 is, for example, a non-temporary tangible medium. The non-temporary tangible media include magnetic disks, optical magnetic disks, CD-ROM (Compact Disk Read Only Memory), DVD-ROM (Digital Versatile Disk Read Only Memory), semiconductor memory, etc., which are connected via the interface 14.

The input device 15 has the function of inputting data and processing instructions. The input device 15 is, for example, a keyboard or a mouse.

The output device 16 has the function to output data. The output device 16 is, for example, a display device such as a liquid crystal display device, or a printing device such as a printer.

When the system verification program generation program is delivered to the computer 10 via communication lines, the computer 10 may expand the delivered program to the main memory device 12 and execute the above process.

Some or all of the components may be realized by general-purpose or dedicated circuitry, processors, or combinations of these. These may consist of a single chip or a number of chips connected via a bus. Some or all of each component may be realized by a combination of the above-mentioned circuits, etc. and programs.

When some or all of each component is realized by multiple information processing devices, circuits, etc., the multiple information processing devices, circuits, etc. may be centrally located or distributed. For example, the information processing devices, circuits, etc. may be implemented as a client-and-server system, cloud computing system, etc., each of which is connected via a communication network.

Next, an overview of the present invention will be described. FIG. 18 is a block diagram showing an outline of the system verification program generation device according to the present invention. The system verification program generation device 20 according to the present invention is equipped with a search unit 21 (e.g., execution entity/parameter search unit 120) that searches a system design for execution entities and parameters of a verification program, which is a program that verifies whether the system design derived from system requirements satisfies one or more verification items extracted from the system requirements.

With such a configuration, the system verification program generation device can reduce the burden on engineers in generating system verification programs.

The search unit 21 may also search for the execution entities and the parameters using search procedures, which are procedures for searching for the execution entities and the parameters of the verification program from the system design.

In addition, the system verification program generation device 20 has a verification template storage unit (e.g., verification template storage unit 140) that stores verification templates, which are templates in which the verification items, the search procedures corresponding to the execution entities, and the search procedures corresponding to the parameters are associated and specified, respectively. The search unit 21 may extract the search procedure corresponding to the execution entity and the search procedure corresponding to the parameter from the verification template including the verification item to be verified, and search for the execution entity and the parameter of the verification program using each extracted search procedure, respectively.

With such a configuration, the system verification program generation device can more easily search for the execution entities and parameters of the verification program.

The system verification program generation device 20 may also be equipped with a generation unit (e.g., verification program generation unit 130) that generates the verification program by assigning the searched parameters to arguments of commands that constitute the verification program.

The system verification program generation device 20 is also equipped with a command template storage unit (e.g., command template storage unit 150) that stores command templates, which are templates in which the execution entities, the parameters, and the commands constituting the verification program are associated and specified, respectively. The generation unit may extract the command from the command template including the searched execution entities and parameters, and assign the searched parameters to the arguments of the extracted command.

With such a configuration, the system verification program generation device can reduce the burden on engineers in generating system verification programs.

The system verification program generation device 20 may also be equipped with an extraction unit (e.g., verification item extraction unit 110) that extracts one or more verification items from the system requirements.

The system verification program generation device 20 may also receive the generated system design from a system design device (e.g., system design device 200) that takes the system requirements as input and generates the system design corresponding to the system requirements.

The system verification program generation device 20 may be communicatively connected to a verification program execution device (e.g., verification program execution device 300) that takes the generated verification program as input and executes the verification program to output verification results.

The verification results output from the verification program execution device may be stored in the verification result storage unit (e.g., verification result storage unit 400).

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A system verification program generation device configured to:
search a system design for execution entities and parameters of a verification program, which is a program that verifies whether the system design derived from system requirements satisfies one or more verification items extracted from the system requirements.

2. The system verification program generation device according to claim 1, wherein the device is configured to search for the execution entities and the parameters using search procedures, which are procedures for searching for the execution entities and the parameters of the verification program from the system design.

3. The system verification program generation device according to claim 2, comprising a verification template storage unit which stores verification templates, which are templates in which the verification items, the search procedures corresponding to the execution entities, and the search procedures corresponding to the parameters are associated and specified, respectively,
wherein the device is configured to extract the search procedure corresponding to the execution entity and the search procedure corresponding to the parameter from the verification template including the verification item to be verified, and searches for the execution entity and the parameter of the verification program using each extracted search procedure, respectively.

4. The system verification program generation device according to claim 1, comprising a generation unit which generates the verification program by assigning the searched parameters to arguments of commands that constitute the verification program.

5. The system verification program generation device according to claim 2, comprising a generation unit which generates the verification program by assigning the searched parameters to arguments of commands that constitute the verification program.

6. The system verification program generation device according to claim 3, further comprising a generation unit which generates the verification program by assigning the searched parameters to arguments of commands that constitute the verification program.

7. The system verification program generation device according to claim 4, further comprising a command template storage unit which stores command templates, which are templates in which the execution entities, the parameters, and the commands constituting the verification program are associated and specified, respectively,
wherein the generation unit extracts the command from the command template including the searched execution entities and parameters, and assigns the searched parameters to the arguments of the extracted command.

8. The system verification program generation device according to claim 5, further comprising a command template storage unit which stores command templates, which are templates in which the execution entities, the parameters, and the commands constituting the verification program are associated and specified, respectively,
wherein the generation unit extracts the command from the command template including the searched execution entities and parameters, and assigns the searched parameters to the arguments of the extracted command.

9. The system verification program generation device according to claim 6, further comprising a command template storage unit which stores command templates, which are templates in which the execution entities, the parameters, and the commands constituting the verification program are associated and specified, respectively,
wherein the generation unit extracts the command from the command template including the searched execution entities and parameters, and assigns the searched parameters to the arguments of the extracted command.

10. The system verification program generation device according to claim 1, comprising an extraction unit which extracts one or more verification items from the system requirements.

11. The system verification program generation device according to claim 2, comprising an extraction unit which extracts one or more verification items from the system requirements.

12. The system verification program generation device according to claim 3, further comprising an extraction unit which extracts one or more verification items from the system requirements.

13. The system verification program generation device according to claim 4, further comprising an extraction unit which extracts one or more verification items from the system requirements.

14. The system verification program generation device according to claim 7, further comprising an extraction unit which extracts one or more verification items from the system requirements.

15. The system verification program generation device according to claim 1, receives the generated system design from a system design device that takes the system requirements as input and generates the system design corresponding to the system requirements.

16. The system verification program generation device according to claim 4, is communicatively connected to a verification program execution device that takes the generated verification program as input and executes the verification program to output verification results.

17. A system verification program generation method comprising:
searching a system design for execution entities and parameters of a verification program, which is a program that verifies whether the system design derived from system requirements satisfies one or more verification items extracted from the system requirements.

18. The system verification program generation method according to claim 17, comprising searching for the execution entities and the parameters using search procedures, which are procedures for searching for the execution entities and the parameters of the verification program from the system design.

19. A non-transitory computer readable recording medium storing a system verification program generation program causing a computer to:
search a system design for execution entities and parameters of a verification program, which is a program that verifies whether the system design derived from system requirements satisfies one or more verification items extracted from the system requirements.

20. The non-transitory computer readable recording medium according to claim 19, wherein the system verification program generation program causing a computer to search for the execution entities and the parameters using search procedures, which are procedures for searching for the execution entities and the parameters of the verification program from the system design.
